(19) United States
(12) Patent Application Publication
(10) Pub. No.: US 2009/0223564 A1
(43) Pub. Date: Sep. 10, 2009

(54) SOLAR CELL AND METHOD FOR MAKING SAME

(75) Inventor: GA-LANE CHEN, Santa Clara, CA (US)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/240,261

(22) Filed: Sep. 29, 2008

(30) Foreign Application Priority Data
Mar. 5, 2008 (CN) 200810300462.X

(51) Int. Cl. H01L 31/00; H01L 21/00

(52) U.S. Cl. 136/261; 438/98; 257/E21.001

(57) ABSTRACT

An exemplary solar cell includes a substrate having a surface, a back metal contact layer formed on the surface of the substrate, a first type semiconductor layer formed on the back metal contact layer, a second type semiconductor layer formed on the first type semiconductor layer, and a CNT film formed on the second type semiconductor layer. The CNT film includes a plurality of successive CNT bundles.

### CROSS-REFERENCE TO RELATED APPLICATIONS

This application is related to commonly-assigned copending applications: Ser. No. 11/967,008, entitled “SOLAR CELL WITH FLEXIBLE SUBSTRATE” (attorney docket number US 14906); Ser. No. 11/967,009, entitled “SOLAR CELL WITH FLEXIBLE SUBSTRATE” (attorney docket number US 14910); Ser. No. 11/933,941, entitled “FLEXIBLE SOLAR CELL” (attorney docket number US 15052); and Ser. No. 12/002,129, entitled “CARBON NANOTUBE FILM STRUCTURE AND METHOD FOR FABRICATING THE SAME”. Disclosures of the above-identified applications are incorporated herein by reference in their entirety.

### BACKGROUND

1. Technical Field

The present invention relates to solar cells and methods for manufacturing the same.

2. Description of Related Art

Generally, a flexible solar cell includes a flexible substrate, a back metal contact layer, a P-type semiconductor layer, an N-type semiconductor layer, and a transparent conductive oxide (TCO) film subsequently formed on the substrate. Indium tin oxide (ITO) has been the most commonly used material for TCO film.

However, ITO has an inferior flexibility and abrasion resistance due to its brittle nature. In addition, the indium component of ITO is rapidly becoming scarce, and therefore is becoming an increasingly expensive commodity, which has fueled demand for lower-cost solutions in recent years.

Therefore, a new solar cell is desired to overcome the above described shortcomings.

### SUMMARY

An exemplary solar cell includes a substrate having a surface, a back metal contact layer formed on the surface of the substrate, a first type semiconductor layer formed on the back metal contact layer, a second type semiconductor layer formed on the first type semiconductor layer, and a CNT film formed on the second type semiconductor layer. The CNT film includes a plurality of successive CNT bundles.

### BRIEF DESCRIPTION OF THE DRAWING

Many aspects of the embodiments can be better understood with references to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

The drawing FIGURE is a schematic, cross-sectional view of a solar cell according to an exemplary embodiment.

### DETAILED DESCRIPTION OF THE EMBODIMENTS

Embodiments will now be described in detail below with reference to the drawing.

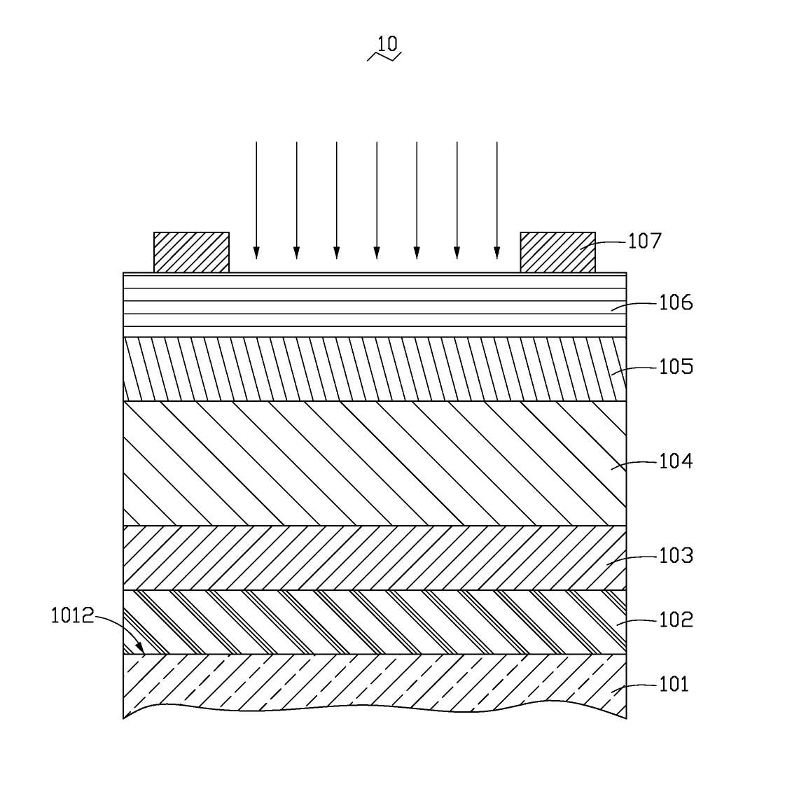

Referring to FIG. 1, a solar cell 100, according to an exemplary embodiment, is shown. The solar cell 100 includes a substrate 101 with a surface 1012. A back metal contact layer 102, a first type semiconductor layer (e.g., a P-type semiconductor layer 103), an active layer 104, a second type semiconductor layer (e.g., an N-type semiconductor layer 105), a carbon nanotube (CNT) layer 106, and a front metal contact layer 107 are formed on the surface 1012 of the substrate 101 in the order written. In the present embodiment, the first type semiconductor layer is the P-type semiconductor layer 103, and the second type semiconductor layer is the N-type semiconductor layer 105. It is to be understood that the first type semiconductor layer can be an N-type semiconductor layer while the second type semiconductor layer can be a P-type semiconductor layer.

The substrate 101 is flexible and so the solar cell 10 is also flexible. The substrate 101 can be made of polymer or stainless steel. The polymer can be, for example, polymide, polyethylene terephthalate (PET), polycarbonate (PC), polymethyl methacrylate (PMMA), or arton (Norbornene). A thickness of the substrate 101 is in an approximate range from 10 microns to 100 microns.

The back metal contact layer 102 can be made of silver, copper, molybdenum, aluminum, copper aluminum alloy, silver copper alloy, or copper molybdenum alloy. The back metal contact layer 102 can be formed on the substrate 101 using any of a variety of common techniques including, but not limited to, sputtering.

The P-type semiconductor layer 103 can be made of P-type amorphous silicon (P-a-Si), particularly, P-type amorphous silicon with hydrogen (P-a-Si:H). Also, the P-type semiconductor layer 103 can be made of III-V group compound semiconductors or II-VI group compound semiconductors, particularly above semiconductors doped with aluminum, gallium, or indium, e.g., aluminum gallium nitride (AlGaN), aluminum gallium arsenide (AlGaAs). The P-type semiconductor layer 103 can be formed by plasma enhanced chemical vapor deposition (PECVD).

The active layer 104 can be made of III-V or I-III-VI group compound semiconductors, e.g., cadmium telluride (CdTe), copper indium diselenide (CuInSe₂, CIS). Also, The active layer 104 can be made of copper indium gallium diselenide (CuIn₁₋ₓGaSe₂, CIGS). The active layer 104 can be formed on the P-type semiconductor layer using any of a variety of common techniques including, but not limited to, chemical vapor deposition, or sputtering.

The N-type semiconductor layer 105 can be made of N-type amorphous silicon (N-a-Si), particularly, N-type amorphous silicon with hydrogen (N-a-Si:H). Also, the N-type semiconductor layer 105 can be made of III-V group compound semiconductors or II-VI group compound semiconductors, particularly above semiconductors doped with nitrogen, phosphorus, arsenic, e.g., gallium nitride (GaN), indium gallium phosphide (InGaP). The N-type semiconductor layer 105 can be formed by, for example, PECVD.

The CNT layer 106 functions as a transparent electrically conductive layer of the solar cell 10. The CNT layer 106 can be a single CNT film or a plurality of stacked CNT films. A method for making such CNT film or stacked CNT films are taught in a commonly-assigned copending application: Ser. No. 11/967,008, entitled “Carbon nanotube film structure and method for fabricating the same”, which is incorporated herein by reference in its entirety. If the CNT layer 106 is a single CNT film, the CNT film includes a plurality of successive CNT bundles. All the CNT bundles are aligned in the same direction. If the CNT layer 106 includes two overlapped CNT films, the two CNT films are aligned along different directions. The angle between the aligned directions of the two CNT films is 90°. The two CNT films are combined by van de Warrls attractive force to form a stable layer structure. Each CNT film includes a plurality of successive CNT bundles, all of which are aligned in the same direction. After being treated with ethanol, the CNTs compact/shrink to bundles, and a space/distance is formed between every two adjacent bundles in each CNT film. Bundles in two films cross with each other to form a microporous structure. The diameter of the respective micropores is in an approximate range of 10 nanometers to 10 microns. It should be noted that the CNT layer 106 can include more than two overlapped CNT films. The total number of the CNT films is arbitrary and depends on the actual needs/use.

In the present embodiment, the CNT layer 106 is a single CNT film. The thickness of the CNT layer 106 can be in an approximate range from 10 nm to 100 nm. The CNT layer 106 is light pervious with a transmittance of more than 75%.

The front metal contact layer 107 can be made of silver, copper, molybdenum, aluminum, copper aluminum alloy, silver copper alloy, or copper molybdenum alloy. The front metal contact layer 107 can be formed on the CNT layer 106 using any of a variety of common techniques including, but not limited to, sputtering. The front metal contact layer 107 has a high electrical conductivity. The front metal contact layer 107 can be formed by, for example, sputtering.

One or more anti-reflective coatings (not shown) can be applied on the front metal contact layer 107 to improve the solar cell's 10 ability to collect incident light.

In order to improve the waterproofing ability of the solar cell 10, a protective layer (not shown) can be formed on the front metal contact layer 107. The protective layer can be made of resin.

The CNT layer 106 is substantially more mechanically robust than ITO films. Furthermore, the CNT layer 106 is chemically resistant and is manufactured from carbon, which is one of the most abundant elements on Earth. Therefore, the cost of the CNT layer 106 is relatively low.

A method for making the solar cell 10 is also provided. The method includes the steps of: (a) forming the back metal contact layer 102 on the surface 1012 of the substrate 101 by, for example, sputtering; (b) forming the P-type semiconductor layer 103 on the back metal contact layer 102 using methods such as, chemical vapor deposition (CVD); (c) forming the active layer 104 on the P-type semiconductor layer 103 using, for example, CVD; (d) forming the N-type semiconductor layer 105 on the active layer 104 using, for example, CVD; (e) forming the CNT layer 106 on the N-type semiconductor layer; and (f) forming the front metal contact layer 107 on the CNT layer 106 by methods, such as, screen printing, sputtering, and so on.

The step (e) can further include the substeps of: (e1) providing an array of CNTs, quite suitably, providing a super-aligned array of CNTs; (e2) pulling out a CNT film from the array of CNTs, by using a tool (e.g., adhesive tape or another tool allowing multiple CNTs to be gripped and pulled simultaneously); and (e3) directly disposing the CNT film on the surface of the N-type semiconductor layer 105, thus forming the CNT layer 106.

In step (e1), the CNT array can be a single-walled CNT array or a multi-walled CNT array. A given super-aligned array of CNTs can be formed by the substeps of: providing a substantially flat and smooth substrate; forming a catalyst layer on the substrate; annealing the substrate with the catalyst at a temperature in the approximate range from 700° C. to 900° C. in air for about 30 to 90 minutes; heating the substrate with the catalyst at a temperature in the approximate range from 500° C. to 740° C. in a furnace with a protective gas therein; and supplying a carbon source gas into the furnace for about 5 to 30 minutes and growing a super-aligned array of the CNTs from the substrate.

In step (e2), the first CNT film can be pulled out from the array of CNTs by the substeps of: selecting a plurality of CNT segments having a predetermined width; and pulling the CNT segments at an even/uniform speed to form the CNT film.

During the pulling process, as the initial CNT segments are drawn out, other CNT segments are also drawn out end to end, due to the van der Waals attractive force between ends of the adjacent segments. This process of drawing ensures a successive CNT film can be formed.

In the present embodiment, because the CNTs obtained from the super-aligned array of CNTs are very pure and the specific surface areas of the CNTs are extremely high, the CNTs are quite viscous. Accordingly, the CNT film can be directly adhered to the surface of the N-type semiconductor layer 105.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A solar cell comprising:
a substrate having a surface;
a back metal contact layer formed on the surface of the substrate;
a first type semiconductor layer formed on the back metal contact layer;
a second type semiconductor layer formed on the first type semiconductor layer; and
a CNT film formed on the second type semiconductor layer, the CNT film comprising a plurality of successive CNT bundles.

2. The solar cell as claimed in claim 1, wherein all the CNT bundles are aligned in the same direction.

3. The solar cell as claimed in claim 1, wherein the CNT bundles are joined by van de Warrls attractive force.

4. The solar cell as claimed in claim 1, wherein each CNT is a single-walled CNT or a multi-walled CNT.

5. The solar cell as claimed in claim 1, wherein the substrate is flexible.

6. The solar cell as claimed in claim 1, further comprising an active layer sandwiched between the first type semiconductor layer and the second type semiconductor layer.

7. The solar cell as claimed in claim 1, further comprising a front metal contact layer formed on the CNT film.

8. A solar cell comprising:
a substrate having a surface;
a back metal contact layer formed on the surface of the substrate;
a first type semiconductor layer formed on the back metal contact layer;
a second type semiconductor layer formed on the first type semiconductor layer; and
a CNT layer formed on the second type semiconductor layer, the CNT layer comprising at least two overlapped CNT films aligned along different directions, each CNT film comprising a plurality of successive CNT bundles, the CNT bundles all being aligned in the same direction.

9. The solar cell as claimed in claim 8, wherein all the CNT bundles of each CNT film are aligned in the same direction.

10. The solar cell as claimed in claim 8, wherein the CNT bundles of each CNT film are joined by van de Warrls attractive force.

11. The solar cell as claimed in claim 8, wherein the CNT film further comprises a plurality of micropores defined between the carbon nanotube bundles.

12. The solar cell as claimed in claim 8, wherein each CNT is a single-walled CNT or a multi-walled CNT.

13. The solar cell as claimed in claim 8, wherein the substrate is flexible.

14. The solar cell as claimed in claim 8, further comprising an active layer sandwiched between the first type semiconductor layer and the second type semiconductor layer.

15. The solar cell as claimed in claim 8, further comprising a front metal contact layer formed on the CNT layer.

16. A method for making a solar cell, the method comprising:
(a) forming a back metal contact layer formed on a surface of the substrate;
(b) forming a first type semiconductor layer on the back metal contact layer;
(c) forming a second type semiconductor layer on the first type semiconductor layer; and
(d) forming a CNT layer on the second type semiconductor layer, the CNT layer being comprised of at least one CNT film, each CNT film comprising a plurality of CNTs.

17. The method as claimed in claim 16, wherein the step (d) comprises: (d1) pulling out a CNT film from an array of CNTs by using a tool; and (d2) disposing the CNT film on the second type semiconductor.

18. The method as claimed in claim 17, wherein the step (d1) comprises: selecting a plurality of CNT segments having a predetermined width; and pulling the CNT segments at an even speed to form the CNT film.
